(19) United States
(12) Patent Application Publication
(10) Pub. No.: US 2010/0307553 A1
(43) Pub. Date: Dec. 9, 2010

(54) ENGINEERING LIGHT MANIPULATION IN STRUCTURED FILMS OR COATINGS

(76) Inventors: ANTHONY DEFRIES, Los Angeles, CA (US); MARK BRONGERSMA, Redwood City, CA (US)

Correspondence Address: MATTER, INC., 149 S. BARRINGTON AVE #757, LOS ANGELES, CA, 90049, US

(21) Appl. No.: 12/546,559

(22) Filed: Aug. 24, 2009

Related U.S. Application Data
(60) Provisional application No. 61/091,997, filed on Aug. 26, 2008.
(60) Provisional application No. 61/094,331, filed on Sep. 4, 2008.

(51) Int. Cl. H01L 31/0216; C23C 16/22; C23C 16/44; B05D 1/18; C23C 14/34; C23C 14/14; C23C 16/06; C23C 16/00; B05D 1/02; H01L 31/18

(52) U.S. Cl. 136/243; 427/585; 427/586; 427/596; 427/580; 427/248.1; 427/421.1; 427/430.1; 204/192.12; 427/254; 427/443.2; 427/440; 427/435; 204/192.15; 427/597; 427/250; 427/255.11; 427/427; 438/57

(57) ABSTRACT

The present disclosure concerns a means to use light manipulation in engineered or structured coatings for thermal or photothermal effects and/or refractive and reflective index management. Such metallic, nonmetallic, organic or inorganic metamaterials or nanostructures could be used to manipulate light or energy for thermal or photothermal effects and/or refractive and reflective index management on or in any material or substrate on or in any material or substrate. The light scattering properties of metallic particles and film can be used to tune such coatings, structures or films over a broad spectrum.

### CROSS REFERENCE TO RELATED APPLICATIONS

This application claims benefit of and priority to U.S. Provisional Patent Application No. 61/091,997 filed Aug. 26, 2008 entitled “Light Manipulation in Engineered or Structured Coatings for Thermal and Photovoltaic Effects” and No. 61/094,331 filed Sep. 4, 2008 entitled “Light Manipulation in Engineered or Structured Coatings for Thermal and Photovoltaic Effects” which application is incorporated herein by reference in its entirety.

### BACKGROUND

1. Field

This disclosure relates to the engineering of metallo-dielectric films or coatings incorporating metallic, nonmetallic, organic and inorganic metamaterials or nanostructures to manipulate light or energy for thermal or photothermal effects and/or for refractive and reflective index management. This invention also relates to the use of metallic, nonmetallic, organic or inorganic metamaterials or nanostructures to manipulate light or energy for thermal or photothermal effects and/or refractive and reflective index management on or in any material or substrate on or in any material or substrate. The light scattering properties of metallic particles and film can be used to tune such coatings, structures or films over a broad spectrum. The present disclosure concerns the use or application of such coatings or structures for control of light-matter interactions or for control of thermal and photothermal effects through the management of reflective or refractive surface index properties. The invention is also addressed to depositing such films, coatings or structures on various substrates to influence or control such characteristics as optical and thermal absorption, conduction, radiation, emissivity, reflectivity and scattering for thermal radiation engineering and/or features as absorption, appearance, color, concentration, conduction, contraction, convection, decoration, design, emission, expansion, finish, insulation, permeability, radiation, reflection, resistance, texture and transmission. Strong light-matter interactions in metallic and non-metallic nanostructures have demonstrated their ability to absorb light and energy more precisely and efficiently than other materials.

2. Related Art

Coatings, film, ink and paint are widely used in all forms of human endeavor. Examples include commercial, industrial, medical, personal, residential and social. Industrial coatings, treatments and paint are used in many applications such as building interiors/exteriors, computers, consumer electronic devices, cosmetics, electrical, fabrics, furniture, home appliances, infrastructure, internal/external structural surfaces, telecommunications, luxury goods, mechanical and industrial equipment, media, medical devices and medical supplies. In addition to aesthetics of appearance, color, decoration, design and finish coatings are used for protection e.g. impermeability, hydrophobicity, shielding and resistance to electromagnetic, radio frequency, ultraviolet or other radiation. The acquisition of raw materials, manufacture production, transportation and application of such coatings consumes enormous amounts of energy and produces even greater volumes of green house gasses, toxic waste products and other harmful emissions. Conventional coatings contain a high proportion of toxic materials and petrochemical products or derivatives. In the last half-century titanium and other metal oxides have been identified as possessing particular light scattering/absorbing properties. Such materials have been incorporated into many of these coatings.

The development of structured coatings, thin films or other materials using the invention described herein could replace conventional paint, film or other protective coatings. At present these materials contain a high proportion of toxic hydrocarbons and petrochemical products or derivatives. This generates significant processing, waste, energy demands and costs. Substituting earth abundant non-toxic and recyclable materials can offer very substantial ecological and economic benefits. The use of renewable alternative energy sources can reduce fossil fuel consumption and emissions. The ability to control the fluctuation of internal or external temperature in a building or structure offers significant energy savings. These are all critical factors in managing the supply and consumption of global energy. The benefits will be invaluable to owners, operators and occupants of buildings or other structures. The producers of building, construction and fabrication materials will likewise achieve significant economic and ecological benefits. The manufacturers of materials used in a variety of sectors and structural forms e.g. automotive, aviation, construction, engineering, transportation, etc. will realize substantial economic and ecological benefits. The invention described herein provides a method to influence temperature-dependent heat transport by modifying spectral emissivity and other features. The method concerns the engineering of active/passive wavelength and temperature dependent tunable coatings.

Electromagnetic energy in the form of solar and thermal radiation is responsible for many different effects including expansion, contraction, deformation, distortion, oxidation, decay, conductive heating and cooling in a broad range of materials. Electromagnetic energy is not commonly used to influence the appearance of materials as described in this invention. Many industrial applications commonly used in construction, engineering, transportation and other sectors require external or internal insulation treatments or coatings to manage such effects. Ceramic-metal composites have been identified as solar selective absorbers and reflectors. These materials can be configured to allow for selective management of radiation absorption and thermal emission and/or for refractive and reflective index management. Current deposition methodologies for these materials require multiple layers and incorporate random or disparate nanostructures of different metals. The invention described in this application concerns more precise engineering and control of nanostructured features. These features may include specific properties of individual particles or clusters i.e. composition, size, density, spatial relationships, shape, uniformity, spacing, morphology, distribution, substrate spatial relationships, surface texture, properties, distance and similar variations. Management of any or all these parameters will permit access to a broader range of wavelength and temperature dependent characteristics and increase spectral efficiency. Films or coatings engineered to incorporate the features described will significantly extend performance, provide additional performance in the form of visual effects or appearance and reduce costs. Control of wavelength resonant frequency effects to exploit the collective oscillation of surface electrons in nanostructured materials can be used to manage radiation, absorption and thermal emission and/or refractive and reflective index values more efficiently. Variations and gradients of tint, shade and color will be accessible over the entire spectrum including the real and imaginary parts of spectral index values.

The development of optical cavities for laser applications is well known. Photons trapped in an optical cavity repeatedly interact with emitters located inside the cavity. If the optical quality is high, photons are trapped for longer periods of time and interaction between light and matter is enhanced. Repeated interaction can create an emission feedback control mechanism. Metallic nanostructures offer a unique opportunity to substantially increase the rate of emissions through surface plasmon excitations, i.e. collective electron oscillations. It has been established that metallic antenna nanostructures enable strong field concentration by means of phase matching freely propagating light waves to local antenna modes. An important aspect of the invention described herein concerns the means to capture and concentrate the maximum light energy by the most efficient combination of nanostructured metallic, nonmetallic, organic, metalorganic or metamaterials materials. A feature of the invention described herein may include incorporating said materials in an antenna, receiver, collector or concentrating device for or as part of a plasmonic or thermal material structure or design.

### BRIEF SUMMARY OF THE INVENTION

The present disclosure concerns a means to use light manipulation in engineered or structured coatings for thermal or photothermal effects and/or refractive and reflective index management. Such metallic, nonmetallic, organic or inorganic metamaterials or nanostructures could be used to manipulate light or energy for thermal or photothermal effects and/or refractive and reflective index management on or in any material or substrate on or in any material or substrate. The light scattering properties of metallic particles and film can be used to tune such coatings, structures or films over a broad spectrum.

### BRIEF DESCRIPTION OF THE DRAWINGS

NOT APPLICABLE

### DETAILED DESCRIPTION OF THE INVENTION

The present disclosure concerns a means to engineer or structure antireflective or metallo-dielectric coatings incorporating metallic, nonmetallic, organic or inorganic metamaterials or nanostructures to manipulate light or energy for thermal or photothermal effects and/or for refractive and reflective index management. The invention also concerns the use of such metallic, nonmetallic, organic or inorganic metamaterials or nanostructures to manipulate light or energy for thermal or photothermal effects and/or for refractive and reflective index management on or in any material or substrate. The light scattering properties of metallic particles and film can be used to tune such coatings, structures or films over a broad spectrum. The present disclosure further concerns the use or application of such coatings for control of light-matter interactions or thermal or photothermal effects through reflective or refractive index management. This invention further concerns the deposition and use of dielectric coatings containing metallic nanostructures to influence or control such characteristics as optical and thermal absorption, conduction, radiation, emissivity, reflectivity and scattering e.g. coatings applied to a substrate exposed to solar or thermal radiation can control absorption and emission. This invention concerns the engineering of coatings to control optical, photonic and plasmonic effects. The use of dielectric or metallic nanostructures to generate superior light-management coatings can enable simultaneous anti-reflection, local field enhancement, light scattering in waveguides, modes or paths, for longer or redirected photons. Metallic, organic, inorganic, nonmetallic, metalorganic, metamaterials, nanostructures, microstructures, nanopatterned structures or nanoengineered materials may be used as antennas or receivers to capture light energy from solar or other sources. The light can be separated into discrete wavelengths using nanopatterned metallic structures or films. The localized field effects can be enhanced to stimulate photon emission rates. These photon emissions can be controlled and focused through metallic nanoparticle absorption, morphology, size, positioning, composition or similar factors. The invention is also addressed to depositing such films, coatings or structures on various substrates to influence or control such features as absorption, appearance, color, concentration, conduction, contraction, convection, decoration, design, emission, expansion, finish, insulation, permeability, radiation, reflection, resistance, texture and transmission.

In an exemplary embodiment metallo-dielectric coatings can boost the efficiency of devices to harvest light and energy in the following ways:
1) Reduce back-reflection of light over a broad wavelength range.
2) Promote forward scattering of light into oblique directions that more strongly interact with the active medium or substrate.
   In a substrate, such as a light-harvesting cell, with a metallo-dielectric coating, a dielectric layer may consist of dielectric elements and metallic nanostructures. The total thickness and composition of the coating can be optimized to reduce back-reflection of light over a broad wavelength range. Subwavelength metallic nanostructures can enable local light concentration and scattering into oblique angles. In a thin device these may enable coupling into waveguide modes.

In an alternative embodiment layers may consist of dielectric films with a monolayer of metallic particles embedded in them. The particle shape, size, composition, spacing, distribution, spatial relationship to the substrate and similar characteristics should be optimized to enable a specific goal, e.g. strong near-field enhancement or light scattering into oblique angles. The total thickness of the metallo-dielectric stack will be chosen to minimize back-reflection and increase coupling into the substrate. Metals exhibiting strong plasmonic resonances may also be advantageous for these types of coatings. Metallo-dielectric coatings can be extremely thin (<1 micron and <100 nm). They can provide many advantages over conventional paint, coatings or other protective treatments including high temperature stability, robustness, resistance to moisture, oxidation, surface deformation and reduced toxicity combined with lower material and processing cost. The structures described could replace conventional paint, film or other protective coatings and treatments. At present these contain a high proportion of toxic materials, hydrocarbons and petrochemical products or derivatives. This generates significant processing, waste, energy demands and costs. Substituting earth abundant non-toxic and recyclable materials can offer very substantial ecological and economic benefits. The use of wavelength resonant frequency management and nanostructured materials will provide more precise control of colorization than any other form of particulate matter, particulation, particle or pigmentation.

In an exemplary embodiment a coating could be deposited on or integrated into a substrate used as or part of a building, construction or fabrication material. The ability to control the appearance of solar cells, modules, arrays and other substrates used in construction or as building materials is becoming increasingly significant in the marketing and sale of products. Even in state of the art solar cells elements including surface shading, uniformity, design, range and color are very limited. As a unique feature of the invention described herein coatings may be designed and used as thin film “paint” to create an entire rainbow palette of colors or designs on surfaces including solar cells. The opportunity to provide color, style and design features in the building and construction/materials industry will have an enormous impact on manufacturers and end consumers. The aviation, automotive and transportation industries will be similarly affected.

In a further embodiment coatings could be used for various cosmetic applications. It is commonly known that cosmetic products often contain harmful and toxic ingredients. Utilizing non-toxic earth abundant materials could offer healthier and greener cosmetic applications, e.g. hair or skin coloring could be achieved with reduced risk of harmful consequences.

In a further embodiment coatings or films may employ concepts and metamaterials to enable greater control over the flow of light. Metallo-dielectric coatings consisting of deep subwavelength metallic nanostructures in a dielectric matrix possess an effective index that can be locally engineered through choice and placement of metallic inclusions. These metamaterial coatings can be designed as superior broadband anti-reflection, light scattering and concentration layers. Coatings can be engineered to produce a desired index variation by altering the metal fraction as a function of distance from the substrate. They can be designed to act as a multilayer antireflective coating or so-called “moth eye” structure exhibiting a substantial reduction in light reflection over single layer antireflection coatings. This structure is highly non-reflective with orderly nanostructured surface variations to allow absorption rather than reflection of incoming light. Such coatings could generate higher efficiencies due to enhanced light concentration and scattering effects. The operation of a metamaterials coating does not rely upon plasmonic effects and could utilize a wide variety of earth abundant metals. Light-harvesting coatings on substrates, including light harvesting cells, can exploit metamaterials concepts. The metal fraction decreases with increasing distance from the substrate. This results in a graded index coating that minimizes reflections over a broad wavelength range. The presence of nanoscale inclusions also induces beneficial light scattering and concentration effects.

An alternative embodiment may address the ways by which solar cells currently utilize a wide variety of different charge extraction schemes. Engineered metallic nanostructures, coatings or other forms derived from the invention described herein may be used on any substrate or medium and in conjunction with any type of charge separation and extraction technique, e.g. a cell based on pn-junctions, Schottky barriers, donor/acceptor interfaces, etc. utilizing a wide range of inorganic and organic semiconductors, electron and hole conduction layers, hybrid organic/inorganic cells, cells containing bucky balls, nanotubes, nanowires, indium tin oxide, etc. Pn junction morphology may include scale, size, separation, stacking density, packing density and vertical, lateral and transverse geometries. This may include surface plasmon-polaritons on extended metal regions, localized surface plasmons on metallic nanostructure, spoof Surface Plasmon-Polaritons (spoof-SPP) in the mid IR and THz regions and/or metamaterials and transformation optics concepts. This may also include structured shapes, spirals, concentric circles, bull's-eyes, targets etc. Materials per this invention may include nanocrystals/lattices, carbon nanotubes, SWCNT, NWCNT, CNW, SNW, nanowire composites and nanomaterial composites. This invention may allow for the exploitation, enhancement, change or suppression of substrate properties e.g. magnetic, electric, dielectric, conductive etc. Further this invention allows for the engineering of pn-junctions or any other form of charge collection mechanism for improved hole-pair dynamics.

In an exemplary embodiment a coating could be deposited on or integrated into a substrate used as a building, construction or fabrication material. This could reduce temperature fluctuations internal to the structure or building in which the substrate is incorporated. A wavelength tunable film where sharp absorption causes onset of emissivity can allow for increased temperature in a black body object to trigger emission or radiation. More thermal energy can be emitted in the form of electromagnetic waves as ambient/radiant temperature increases. Black body temperatures scale to the fourth power. Accordingly this could provide a 20% increase in thermal emission over a range of 0-50° C.

In a further embodiment, a metallo-dielectric coating as described in this invention applied to any substrate exposed to solar or thermal radiation can provide control of absorption through triggered emission. Coating a substrate internal to the building or structure can trigger emission or absorption from internal thermal radiation. Thinner coatings can control emission while thicker coatings can be used to control conductivity. The increase or decrease in thermal emission can be used to measure the performance of the coating. Modifying the spectral emissivity of the film can be used to control wavelength and temperature-dependent heat transport. Plasmon enhanced window glass and plasmon enhanced steel could be created by the technology described herein. In plasmon enhanced glass, metallic nanoparticles scatter a fraction of the light into waveguided modes of the glass and transport this energy to a solar cell (e.g. pn-junction) on the side of the glass. A low index layer thickness and refractive index is chosen to optimize coupling (and minimize decoupling) of light into the waveguide and finally the solar cell. Light concentration enables the solar cells to operate more efficiently. Processing metallo-dielectric coatings and thin film solar cells is feasible on top of engineered steel used in a wide variety of construction to create plasmon enhanced steel. Similar ideas can be applied to a wide range of metallic/non transparent products.

Coatings on glass, steel or any other substrates can act as a lens, absorber and/or an antireflective coating comprising one or more layers of dielectric materials including but not limited to: organic, metallic, nonmetallic, metalorganic, inorganic materials, metamaterials, microstructures or nanostructured metallo-dielectric films. Coatings may include structures that incorporate silicon, silica, air, gas and vacuum-filled chambers.

It is a feature of this invention that the coatings described can be processed using all known methods of application in addition to established commercial and noncommercial or specialized deposition techniques. Coating methods may include but are not limited to: chemical deposition in which a fluid precursor undergoes a chemical change at a solid surface leaving a solid layer (e.g. plating, chemical solution deposition, chemical vapor deposition, plasma assisted chemical vapor deposition, plasmon assisted chemical vapor deposition, laser assisted chemical vapor deposition, laser assisted plasma chemical vapor deposition); physical vapor deposition in which mechanical or thermodynamic means produce a thin film of solid (e.g. thermal evaporator, microwave, sputtering, pulsed laser deposition, cathodic arc deposition, dipping, painting, spraying, annealing); reactive sputtering in which a small amount of non-noble gas such as oxygen or nitrogen is mixed with a plasma-forming gas; and molecular beam epitaxy in which slow streams of an element are directed at the substrate so material deposits one atomic layer at a time.

A feature of this invention is to enable deposition or application of the coatings on various substrates. Coatings may be incorporated in or deposited on any substrate including silicon, glass, metals, glass-metal-glass combinations, metal-glass-metal combinations, polymers or plastics, or self-assembled monolayers, fabrics, organic materials, inorganic materials, fibers, wood, concrete, cement, fabric, textiles, synthetics, skin, hide and other biological materials. Coatings may also be deposited on or incorporated in protective coatings or similar substrate materials.

A feature of this invention is to allow any metallic, ceramic composite, organic, inorganic, nonmetallic, metalorganic, metamaterials, nanostructures, microstructures, nanopatterned structures or nanoengineered materials to be included in coatings. Examples include silicon dioxide, titanium dioxide, silver, gold, and other metals or metal oxides. Such materials may be used for local field enhancement, light scattering, concentration, waveguide, modes or paths for combined or redirected photons. Said materials may be used as antennas or receivers to harvest light or thermal energy from solar or other sources. An exemplary embodiment may include structured nanoantennas contained in or deposited on any substrate, material or light-transparent material used to harvest energy from optical, thermal or electromagnetic excitation.

The various features, methods, means or structures of the invention described herein could be expressed in any combination in any or all of the following or any other architectures, form factors, materials or combination of materials including:

A metallic

A nonmetallic

An organic

An inorganic

A metal organic

A metal organic compound

An organometallic

A metal oxide

A transparent oxide

A transparent conducting oxide

An oxide

A metal oxide film

A metal oxide composite film

A silicon

A silica

A silicate

A ceramic

A composite

A compound

A polymer

A plastic

An organic composite thin film

An organic composite coating

An inorganic composite thin film

An inorganic composite coating

An organic and inorganic composite thin film

An organic and inorganic composite coating

A thin film crystal lattice nanostructure

An active photonic matrix

A flexible multi-dimensional film, screen or membrane

A microprocessor

A MEMS or NEMS device

A microfluidic or nanofluidic chip

A single nanowire, nanotube or nanofiber

A bundle of nanowires, nanotubes or nanofibers

A cluster, array or lattice of nanowires, nanotubes or nanofibers

A single optical fiber

A bundle of optical fibers

A cluster, array or lattice of optical fibers

A cluster, array or lattice of nanoparticles

Designed or shaped single nanoparticles at varying length scales

Nanomolecular structures

Nanowires, dots, rods, particles, tubes, sphere, films or like materials in any combination

Nanoparticles suspended in various liquids or solutions

Nanoparticles in powder form

Nanoparticles in the form of pellets, liquid, gas, plasma or otherwise

Nanostructures, nanoreactors, microstructures, microreactors, macrostructures or other devices

Combinations of nanoparticles or nanostructures in any of the forms described or any other form

Nanopatterned materials

Nanopatterned nanomaterials

Nanopatterned micro materials

Micropatterned metallic materials

Microstructured metallic materials

Metallic micro cavity structures

Metal dielectric material

Metal dielectric metal materials

Autonomous self-assembled or self-assembling structure of any kind

Combination of dielectric metal materials or metal dielectric metal materials

A semiconductor

Semiconductor materials including CMOS, SOI, germanium, quartz, glass, inductive, conductive or insulation materials, integrated circuits, wafers, or microchips

An insulator

A conductor

A paint, coating, powder or film in any form containing any of the materials identified herein or any other materials in any combination

Combinations of nanoparticles or nanostructures in any of the forms described or any other form

All or any of the materials or forms described herein may be designed, used or deployed on or in flexible, elastic, conformable structures. Said structures or surface areas may be expanded or enlarged by the use of advanced non-planar, non-linear geometric and spatial configurations.

In any embodiment or description contained herein the method of enabling the various functions, tasks or features contained in this invention includes performing the operation of some or all of the steps outlined in conjunction with the preferred processes or devices. This description of the operation and steps performed is not intended to be exhaustive or complete or to exclude the performance or operation of any additional steps or the performance or operation of any such steps or the steps in any different sequence or order.

The foregoing means and methods are described as exemplary embodiments of the invention. Those examples are intended to demonstrate that any of the aforementioned steps, processes or devices may be used alone or in conjunction with any other in the sequence described or in any other sequence.

It is also understood that the examples and implementations described herein are for illustrative purposes only and that various modifications or changes in light thereof will be suggested to persons skilled in the art and are to be included within the spirit and purview of this application.

1. A method in which metallo-dielectric coatings can boost the efficiency of devices to harvest light and energy:
where at least the back-reflection of light is reduced over a broad wavelength range,
where at least the coatings promote forward scattering of light into oblique directions that more strongly interact with the active medium or substrate,
where at least a substrate with a metallo-dielectric coating contains one layer of a solar cell consists of dielectric elements and metallic nano structures,
where at least a substrate with a metallo-dielectric coating contains the total thickness and composition of the coating is optimized to reduce back-reflection of light over a broad wavelength range,
where at least a substrate with a metallo-dielectric coating contains subwavelength metallic nanostructures to enable local light concentration and scattering into oblique angles,
where at least a substrate with a metallo-dielectric coating contains may enable coupling into waveguide modes in a thin device.

2. A method of claim 1 in which layers may consist of dielectric films with a monolayer of metallic particles embedded in them:
where at least the particle shape, size, composition, spacing, distribution, spatial relationship to the substrate and similar characteristics should be optimized to enable a specific goal, e.g. strong near-field enhancement or light scattering into oblique angles,
where at least the total thickness of the metallo-dielectric stack will be chosen to minimize back-reflection and increase coupling into the substrate,
where at least metals exhibiting strong plasmonic resonances may be used for these types of coatings,
where at least metallo-dielectric coatings can be extremely thin (<1 micron and <100 nm),
where at least they can provide many advantages over conventional paint, coatings or other protective treatments including high temperature stability, robustness, resistance to moisture, oxidation, surface deformation and reduced toxicity combined with lower material and processing cost,
where at least the structures described could replace conventional paint, film or other protective coatings and treatments,
where at least the coatings can significantly reduce processing, waste, energy demands and costs,
where at least substituting earth abundant non-toxic and recyclable materials can offer very substantial ecological and economic benefits,
where at least the use of wavelength resonant frequency management and nanostructured materials may provide more precise control of colorization than any other form of particulate matter, particulation, particle or pigmentation.

3. The method of claim 1 in which coating could be deposited on or integrated into a substrate used as or part of a building, construction or fabrication material:
where at least the coatings may be designed and used as thin film “paint” to create an entire rainbow palette of colors or designs on surfaces including solar cells.

4. A method of claim 1 where at least coatings or films may employ concepts and metamaterials to enable greater control over the flow of light:
where at least metallo-dielectric coatings consisting of deep subwavelength metallic nanostructures in a dielectric matrix possess an effective index that can be locally engineered through choice and placement of metallic inclusions,
where at least metamaterial coatings can be designed as superior broadband anti-reflection, light scattering and concentration layers,
where at least coatings can be engineered to produce a desired index variation by altering the metal fraction as a function of distance from the substrate,
where at least coatings can be designed to act as a multilayer antireflective coating or so-called “moth eye” structure exhibiting a substantial reduction in light reflection over single layer antireflection coatings,
where at least this structure is highly non-reflective with orderly nanostructured surface variations to allow absorption rather than reflection of incoming light,
where at least such coatings could generate higher efficiencies due to enhanced light concentration and scattering effects.
where at least the operation of a metamaterials coating does not rely upon plasmonic effects and could utilize a wide variety of earth abundant metals,
where at least light-harvesting coatings that exploit metamaterials concepts decrease the metal fraction with increasing distance from the substrate,
where at least light-harvesting coatings that exploit metamaterials result in a graded index coating that minimizes reflections over a broad wavelength range,
where at least light-harvesting coatings that exploit metamaterials include presence of nanoscale inclusions to induce beneficial light scattering and concentration effects.

5. A method of claim 1 where at least engineered metallic nanostructures, coatings or other forms derived from the invention described herein may be used on any substrate or medium and in conjunction with any type of charge separation and extraction technique, e.g. a cell based on pn-junctions, Schottky barriers, donor/acceptor interfaces, etc. utilizing a wide range of inorganic and organic semiconductors, electron and hole conduction layers, hybrid organic/inorganic cells, cells containing bucky balls, nanotubes, nanowires, indium tin oxide, etc.:
where at least pn-junction morphology may include scale, size, separation, stacking density, packing density and vertical, lateral and transverse geometries,
where at least this may include surface plasmon-polaritons on extended metal regions, localized surface plasmons on metallic nanostructure, spoof Surface Plasmon-Polaritons (spoof-SPP) in the mid IR and THz regions and/or metamaterials and transformation optics concepts. This may also include structured shapes, spirals, concentric circles, bull's-eyes, targets etc. Materials per this invention may include nanocrystals/lattices, carbon nanotubes, SWCNT, NWCNT, CNW, SNW, nanowire composites and nanomaterial composites,
where at least structures described in this invention may allow for the exploitation, enhancement, change or suppression of substrate properties e.g. magnetic, electric, dielectric, conductive etc.,
where at least the engineering of pn-junctions or any other form of charge collection mechanism is enabled for improved hole-pair dynamics.

6. A method of claim 1 in which a coating could be deposited on or integrated into a substrate used as a building, construction or fabrication material to reduce temperature fluctuations internal to the structure or building in which the substrate is incorporated:
where at least a wavelength tunable film where sharp absorption causes onset of emissivity can allow for increased temperature in a black body object to trigger emission or radiation,
where at least thermal energy can be emitted in the form of electromagnetic waves as ambient/radiant temperature increases,
where at least a 20% increase in thermal emission over a range of 0-50° C. is enabled since black body temperatures scale to the fourth power.

7. A method of claim 1 where at least a metallo-dielectric coating applied to any substrate exposed to solar or thermal radiation can provide control of absorption through triggered emission:
where at least coating a substrate internal to the building or structure can trigger emission or absorption from internal thermal radiation,
where at least thinner coatings can control emission while thicker coatings can be used to control conductivity,
where at least the increase or decrease in thermal emission can be used to measure the performance of the coating,
where at least modifying the spectral emissivity of the film can be used to control wavelength and temperature-dependent heat transport,
where at least plasmon enhanced window glass and/or plasmon enhanced steel are enabled,
where at least in plasmon enhanced window glass, metallic nanoparticles scatter a fraction of the light into waveguided modes of the glass and transport this energy to a solar cell (e.g. pn-junction) on the side of the glass,
where at least in plasmon enhanced window glass, the low index layer thickness and refractive index is chosen to optimize coupling (and minimize decoupling) of light into the waveguide and the solar cell,
where at least in Plasmon enhanced window glass, light concentration enables the solar cells to operate more efficiently,
where at least in Plasmon enhanced steel processing metallo-dielectric coatings and thin film solar cells may be deposited on engineered steel and a wide range of metallic/non transparent products.

8. A method of claim 1 in which coatings on glass, steel or any other substrates can act as a lens, absorber and/or an antireflective coating comprising one or more layers of dielectric materials including but not limited to: organic, metallic, nonmetallic, metalorganic, inorganic materials, metamaterials, microstructures or nanostructured metallo-dielectric films:
where at least coatings may include structures that incorporate silicon, silica, air, gas and vacuum-filled chambers.

9. A method in which coatings can be processed using all known methods of application in addition to established commercial and noncommercial or specialized deposition techniques:
where at least coating methods may include but are not limited to: chemical deposition in which a fluid precursor undergoes a chemical change at a solid surface leaving a solid layer (e.g. plating, chemical solution deposition, chemical vapor deposition, plasma assisted chemical vapor deposition, plasmon assisted chemical vapor deposition, laser assisted chemical vapor deposition, laser assisted plasma chemical vapor deposition); physical vapor deposition in which mechanical or thermodynamic means produce a thin film of solid (e.g. thermal evaporator, microwave, sputtering, pulsed laser deposition, cathodic arc deposition, dipping, painting, spraying, annealing); reactive sputtering in which a small amount of non-noble gas such as oxygen or nitrogen is mixed with a plasma-forming gas; and molecular beam epitaxy in which slow streams of an element are directed at the substrate so material deposits one atomic layer at a time.

10. A method of claim 9 in which deposition or application of the coatings on various substrates is enabled:
where at least coatings may be incorporated in or deposited on any substrate including silicon, glass, metals, glass-metal-glass combinations, metal-glass-metal combinations, polymers or plastics, or self-assembled monolayers, fabrics, organic materials, inorganic materials, fibers, wood, concrete, cement, fabric, textiles, synthetics, skin, hide and other biological materials,
where at least coatings may also be deposited on or incorporated in protective coatings or similar substrate materials.

11. A method of claim 9 where any metallic, ceramic composite, organic, inorganic, nonmetallic, metalorganic, metamaterials, nanostructures, microstructures, nanopatterned structures or nanoengineered materials may be included in coatings:
where at least examples include silicon dioxide, titanium dioxide, silver, gold, and other metals or metal oxides,
where at least such materials may be used for local field enhancement, light scattering, concentration, waveguide, modes or paths for combined or redirected photons,
where at least said materials may be used as antennas or receivers to harvest light or thermal energy from solar or other sources,
where at least coatings may include structured nanoantennas contained in or deposited on any substrate, material or light-transparent material used to harvest energy from optical, thermal or electromagnetic excitation.

12. A method of claim 9 which contains at least any or all of the following or any other architectures, form factors, materials or combination of materials including a metallic; a nonmetallic; an organic, an inorganic; a metal organic; a metal organic compound; an organometallic; a metal oxide, a transparent oxide, a transparent conducting, an oxide; a metal oxide film; a metal oxide composite film; a silicon; a silica; a silicate; a ceramic; a composite; a compound; a polymer; a plastic; an organic composite thin film; an organic composite coating; an inorganic composite thin film; an inorganic composite coating; an organic and inorganic composite thin film; an organic and inorganic composite coating; a thin film crystal lattice nanostructure; an active photonic matrix; a flexible multi-dimensional film; screen or membrane; a microprocessor; a MEMS or NEMS device; a microfluidic or nanofluidic chip; a single nanowire, nanotube or nanofiber; a bundle of nanowires, nanotubes or nanofibers; a cluster, array or lattice of nanowires, nanotubes or nanofibers; a single optical fiber; a bundle of optical fibers; a cluster, array or lattice of optical fibers; a cluster, array or lattice of nanoparticles; designed or shaped single nanoparticles at varying length scales; nanomolecular structures; nanowires, dots, rods, particles, tubes, sphere, films or like materials in any combination; nanoparticles suspended in various liquids or solutions; nanoparticles in powder form; nanoparticles in the form of pellets, liquid, gas, plasma or otherwise; nanostructures, nanoreactors, microstructures, microreactors, macrostructures or other devices; combinations of nanoparticles or nanostructures in any of the forms described or any other form; nanopatterned materials; nanopatterned nanomaterials; nanopatterned micro materials; micropatterned metallic materials; microstructured metallic materials; metallic micro cavity structures; metal dielectric material; metal dielectric metal materials; autonomous self-assembled or self-assembling structure of any kind; combination of dielectric metal materials or metal dielectric metal materials; a semiconductor; semiconductor materials including SOI, gallium arsenide, germanium, quartz, glass, inductive, conductive or insulation materials, integrated circuits, wafers, or microchips; an insulator; a conductor; a paint, coating, powder or film in any form containing any of the materials identified herein or any other materials in any combination; combinations of nanoparticles or nanostructures in any of the forms described or any other form; all or any of the materials or forms described herein may be designed, used or deployed on or in flexible, elastic, conformable structures; said structures or surface areas may be expanded or enlarged by the use of advanced non-planar, non-linear geometric and spatial configurations.

13. A method where coatings could be used for various cosmetic applications:
where at least utilizing non-toxic earth abundant materials could offer healthier and greener cosmetic applications, e.g. hair or skin coloring could be achieved with reduced risk of harmful consequences.
